(19) United States
(12) Patent Application Publication
(10) Pub. No.: US 2025/0248015 A1
(43) Pub. Date: Jul. 31, 2025

(54) SEMICONDUCTOR DEVICE

(71) Applicant: Mitsubishi Electric Corporation, Tokyo (JP)

(72) Inventor: Toshihide OKA, Tokyo (JP)

(73) Assignee: Mitsubishi Electric Corporation, Tokyo (JP)

(21) Appl. No.: 18/866,859

(22) PCT Filed: Oct. 5, 2022
(86) PCT No.: PCT/JP2022/037290

§ 371 Date: Nov. 18, 2024

(51) Int. Cl. H05K 9/00; H01S 5/00; H05K 1/02

(52) U.S. Cl. CPC H05K 9/0037; H01S 5/0014; H05K 1/0277; H05K 2201/2027

(57) ABSTRACT

An optical device (1) includes a feedthrough substrate (2). The feedthrough substrate (2) is connected to one end of the flexible substrate (3). A cap (4) covers the one end of the flexible substrate (3). The feedthrough substrate (2) includes a second wiring pattern (8) joined to the first wiring pattern (12) at the one end of the flexible substrate (3) by solder (13). The guide slope (15a, 15b) is provided on an inner surface of the cap (4).

### FIELD

The present disclosure relates to a semiconductor device including a flexible substrate.

### BACKGROUND

A semiconductor device in which one end of a flexible substrate is solder-joined to a feedthrough substrate of an optical device is used. The other end of the flexible substrate is connected to an inspection jig or a circuit substrate (for example, see PTL 1).

### CITATION LIST

### Patent Literature

[PTL 1] JP 2000-77122 A

### SUMMARY OF THE INVENTION

### Problem to be Solved by the Invention

There is an issue that, when the semiconductor device is attached to the inspection jig or is mounted on the substrate, the flexible substrate is sharply bent near a solder joining portion, and the flexible substrate is disconnected. In recent years, a thickness of the flexible substrate is increased, and the flexible substrate is likely to be disconnected by application of large stress.

The present disclosure is made to solve the above-described issue, and an object of the present disclosure is to provide a semiconductor device that can prevent disconnection of the flexible substrate.

### Solution to Problem

A semiconductor device according to the present disclosure includes: a flexible substrate; an optical device including a feedthrough substrate connected to one end of the flexible substrate; and a cap covering the one end of the flexible substrate, wherein the flexible substrate includes a first wiring pattern, the feedthrough substrate includes a second wiring pattern joined to the first wiring pattern at the one end of the flexible substrate by solder, and the guide slope is provided on an inner surface of the cap.

### Advantageous Effects of Invention

In the present disclosure, the one end of the solder-joined flexible substrate is covered with the cap, and the guide slopes are provided on the inner surface of the cap. Therefore, the flexible substrate is gently bent along the guide slope. Accordingly, the flexible substrate is not sharply bent near the solder joining portion, which makes it possible to prevent disconnection.

### BRIEF DESCRIPTION OF THE DRAWINGS

FIG. 1 is a perspective view illustrating a semiconductor device according to Embodiment 1.

FIG. 2 is a cross-sectional view illustrating a solder joining portion of the semiconductor device according to Embodiment 1 in an enlarged manner.

FIG. 3 is a cross-sectional view illustrating the cap according to Embodiment 1.

FIG. 4 is a front view illustrating the cap according to Embodiment 1.

FIG. 5 is a cross-sectional view illustrating a use state of the semiconductor device according to Embodiment 1.

FIG. 6 is a cross-sectional view illustrating a solder joining portion of a semiconductor device according to the comparative example in an enlarged manner.

FIG. 7 is a cross-sectional view illustrating a solder joining portion of a semiconductor device according to Embodiment 2 in an enlarged manner.

### DESCRIPTION OF EMBODIMENTS

A semiconductor device according to the embodiments of the present disclosure will be described with reference to the drawings. The same components will be denoted by the same symbols, and the repeated description thereof may be omitted.

### Embodiment 1

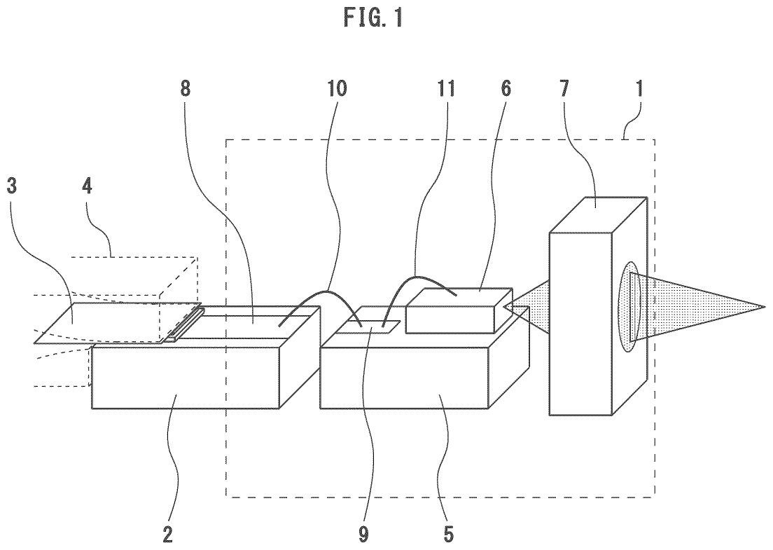

FIG. 1 is a perspective view illustrating a semiconductor device according to Embodiment 1. An optical device 1 for light speed communication includes a feedthrough substrate 2. The feedthrough substrate 2 is connected to one end of a flexible substrate 3. A cap 4 covers the one end of the flexible substrate 3.

The optical device 1 includes, in addition to the feedthrough substrate 2, a carrier 5, a laser diode chip 6 provided on the carrier 5, and a lens 7. A wiring pattern 8 is provided on the feedthrough substrate 2. The wiring pattern 8 is connected to a wiring pattern 9 of the carrier 5 through a wire 10. The wiring pattern 9 is connected to the laser diode chip 6 through a wire 11. Light output from the laser diode chip 6 is condensed by the lens 7.

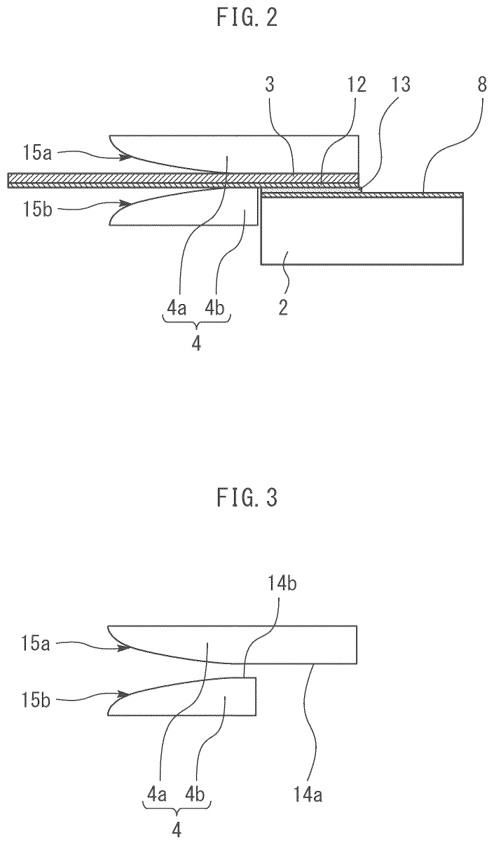

FIG. 2 is a cross-sectional view illustrating a solder joining portion of the semiconductor device according to Embodiment 1 in an enlarged manner. FIG. 3 is a cross-sectional view illustrating the cap according to Embodiment 1. A wiring pattern 12 is provided on a front surface of the flexible substrate 3. The wiring pattern 8 is provided on an upper surface of the feedthrough substrate 2. The wiring pattern 8 is joined to the wiring pattern 12 at the one end of the flexible substrate 3 by solder 13. The wiring pattern 12 and the wiring pattern 8 are, for example, copper patterns and are obtained by arranging ground patterns on both sides of a signal line through which a high-frequency signal passes.

The cap 4 includes a cap upper portion 4a and a cap lower portion 4b vertically sandwiching the flexible substrate 3. An inner surface of the cap upper portion 4a is a lower surface of the cap upper portion 4a, and includes a flat portion 14a coming into contact with a rear surface of the flexible substrate 3, and a guide slope 15a disposed on a side close to the other end of the feedthrough substrate 2 as compared with the flat portion 14a. The inner surface of the cap upper portion 4a has no corner between the guide slope 15a and the flat portion 14a, and the guide slope 15a and the flat portion 14a are smoothly connected to each other. An inner surface of the cap lower portion 4b is an upper surface of the cap lower portion 4b, and includes a flat portion 14b coming into contact with the front surface of the flexible substrate 3, and a guide slope 15b disposed on the side close to the other end of the feedthrough substrate 2 as compared with the flat portion 14b. The inner surface of the cap lower portion 4b has no corner between the guide slope 15b and the flat portion 14b, and the guide slope 15b and the flat portion 14b are smoothly connected to each other. The guide slopes 15a and 15b are smooth curved surfaces without a corner. The flat portion 14a and the flat portion 14b face each other and are parallel to each other.

The flexible substrate 3 is inserted into a space between the cap upper portion 4a and the cap lower portion 4b. Since the guide slopes 15a and 15b are provided on the inner surface of the cap 4, an interval between the cap upper portion 4a and the cap lower portion 4b is increased from the one end to the other end of the flexible substrate 3. Note that any one of the guide slopes 15a and 15b may be provided.

The cap upper portion 4a of the cap 4 covers an upper side of the feedthrough substrate 2 at the solder joining portion. When the cap 4 covers upper and lower sides of the feedthrough substrate 2, a size of a product is excessively increased. Therefore, the cap 4 covers only the upper side of the feedthrough substrate 2.

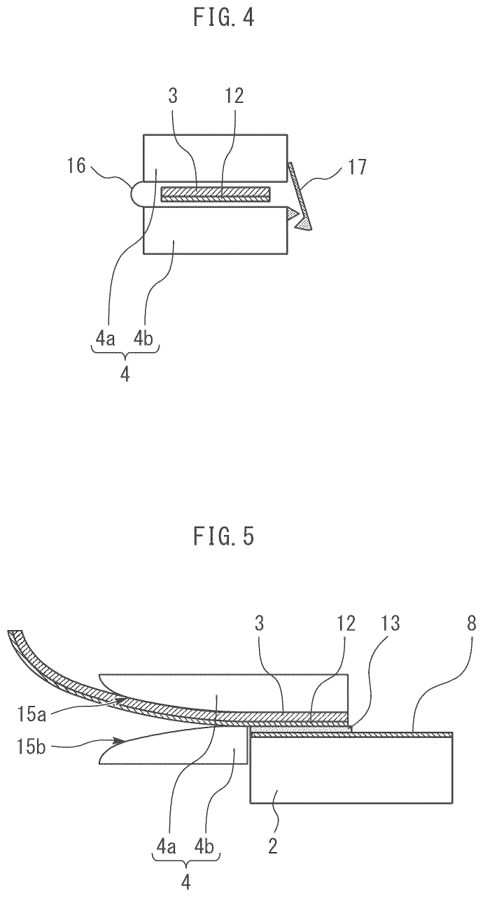

FIG. 4 is a front view illustrating the cap according to Embodiment 1. The cap 4 includes a hinge 16 that connects the cap upper portion 4a and the cap lower portion 4b on one of side surfaces of the cap 4, and a hook 17 that detachably couples the cap upper portion 4a and the cap lower portion 4b on the other of side surface of the cap 4. The hook 17 is released, the one end of the flexible substrate 3 is housed between the cap upper portion 4a and the cap lower portion 4b, and then the hook 17 is locked, which makes it possible to cause the cap 4 to cover the one end of the flexible substrate 3. The cap 4 can be optionally detached by using the hinge 16 and the hook 17. Accordingly, after the flexible substrate 3 is fixed to the feedthrough substrate 2, the cap 4 can be detached and reused.

FIG. 5 is a cross-sectional view illustrating a use state of the semiconductor device according to Embodiment 1. An inspection jig (not illustrated) generating a test signal or a circuit substrate (not illustrated) generating a signal to be provided to the optical device 1 is attached to the other end of the flexible substrate 3. At this time, the flexible substrate 3 is gently bent along the guide slope 15a.

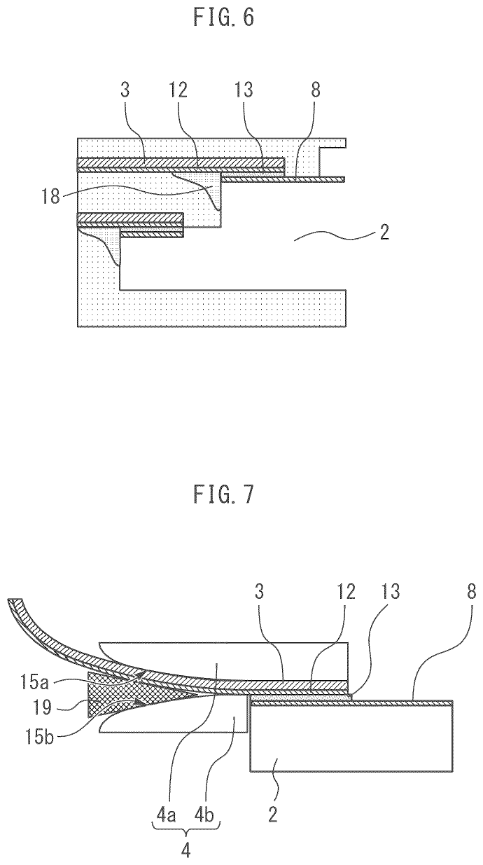

Subsequently, effects by the present embodiment are described while being compared with a comparative example. FIG. 6 is a cross-sectional view illustrating a solder joining portion of a semiconductor device according to the comparative example in an enlarged manner. The flexible substrate 3 and the feedthrough substrate 2 are fixed with a reinforcing resin 18. However, disconnection of the flexible substrate 3 cannot be sufficiently prevented because the flexible substrate 3 is bent near a fixed portion.

On the other hand, in the present embodiment, the one end of the solder-joined flexible substrate 3 is covered with the cap 4, and the guide slopes 15a and 15b are provided on the inner surface of the cap 4. Therefore, the flexible substrate 3 is gently bent along the guide slope 15a or the guide slope 15b. Accordingly, the flexible substrate 3 is not sharply bent near the solder joining portion, which makes it possible to prevent disconnection. Further, it is unnecessary to use a special material for the flexible substrate 3 in order to prevent disconnection, and an existing material can be used. Thus, high-frequency characteristics of the flexible substrate 3 are not affected.

To prevent short circuit, the material of the cap 4 is an insulator such as a resin. To prevent interference from outside, the material of the cap 4 is preferably a radio wave absorber. The radio wave absorber is, for example, a resin mixture containing metal powder. The metal power is, for example, ground powder of natural shungite ore.

### Embodiment 2

FIG. 7 is a cross-sectional view illustrating a solder joining portion of a semiconductor device according to Embodiment 2 in an enlarged manner. An insertion part 19 is inserted into the cap 4, and presses the flexible substrate 3 against the guide slope 15a. This makes it possible to fix a bent shape of the flexible substrate 3. The other components and effects are similar to the components and effects according to Embodiment 1.

### REFERENCE SIGNS LIST

1 optical device; 2 feedthrough substrate; 3 flexible substrate; 4 cap; 4a cap upper portion; 4b cap lower portion; 8 wiring pattern; 12 wiring pattern; 13 solder; 14a, 14b flat portion; 15a, 15b guide slope; 16 hinge; 17 hook; 19 insertion part

1. A semiconductor device comprising:
a flexible substrate;
an optical device including a feedthrough substrate connected to one end of the flexible substrate; and
a cap covering the one end of the flexible substrate,
wherein the flexible substrate includes a first wiring pattern,
the feedthrough substrate includes a second wiring pattern joined to the first wiring pattern at the one end of the flexible substrate by solder, and
the guide slope is provided on an inner surface of the cap,
the flexible substrate is bent along the guide slope,
an insertion part is inserted into the cap and presses the flexible substrate against the guide slope to fix a bent shape of the flexible substrate,
the cap includes a cap upper portion and a cap lower portion vertically sandwiching the flexible substrate,
the cap upper portion covers an upper side of the feedthrough substrate at a solder joining portion between the first wiring pattern and the second wiring pattern, and
a feedthrough substrate-side edge of the cap lower portion comes into contact with the feedthrough substrate.

2. The semiconductor device according to claim 1, wherein the inner surface of the cap includes a flat portion coming into contact with the flexible substrate, and
the guide slope is disposed on a side close to the other end of the feedthrough substrate as compared with the flat portion.

3. The semiconductor device according to claim 2, wherein the inner surface of the cap has no corner between the guide slope and the flat portion.

4. The semiconductor device according to claim 1, wherein the cap upper portion and the cap lower portion vertically and directly sandwiches the flexible substrate, and
an interval between the cap upper portion and the cap lower portion is increased from the one end of the flexible substrate to the other end of the flexible substrate.

5. The semiconductor device according to claim 4, wherein the cap includes a hinge connecting the cap upper portion and the cap lower portion on one of side surfaces of the cap, and a hook detachably coupling the cap upper portion and the cap lower portion on the other of side surface of the cap.

6. (canceled)

7. (canceled)

8. The semiconductor device according to claim 1, wherein a material of the cap is a radio wave absorber.
